(19) United States
(12) Patent Application Publication
(10) Pub. No.: US 2006/0192549 A1
(43) Pub. Date: Aug. 31, 2006

(54) Current sensor with magnetic toroid dual frequency detection scheme

(76) Inventors: David A. Sandquist, St. Paul, MN (US); Andrzej Peczalski, Eden Prairie, MN (US); Nick Demma, Minneapolis, MN (US)

Correspondence Address: Kris T. Fredrick, Esq.;Patent Services, Honeywell International Inc., 101 Columbia Road, Morristown, NJ, 07962, US

(21) Appl. No.: 11/140,016

(22) Filed: Aug. 17, 2005

Related U.S. Application Data
(63) Continuation-in-part of application No. 11/066,788, filed on Feb. 25, 2005.

(51) Int. Cl. G01R 15/20

(52) U.S. Cl. 324/117 R

(57) ABSTRACT

A sensor device comprising a magnetic material having nonlinear magnetic properties within an ambient magnetic flux. The device includes a signal conductor carrying a compound applied electric signal having two frequencies f1 and f2 and coupled to the magnetic material with the ambient magnetic flux to produce a resulting signal. A primary conductor carries a primary current coupled to the magnetic material having nonlinear magnetic properties to change the magnetic flux of the magnetic material and produce the resulting signal. The magnetic material may be open ended or in the shape of a toroid. In the latter case, the device further includes a primary conductor for carrying a primary current coupled to the magnetic material having nonlinear magnetic properties to change the magnetic flux of the magnetic material and produce the resulting signal. The primary and signal conductors are preferably configured as windings on the toroid. When the applied compound electrical signal having two frequencies is a voltage signal the resulting signal is current and when the signal is a current signal, the resulting signal is a voltage. An electrical circuit is used for detecting the resulting signal at frequencies f1=f2 or f1−f2 using a demodulation of the signal to thereby create a low frequency signal f3 related to the ambient magnetic flux magnitude and phase or polarity.

This is a continuation-in-part of a commonly owned U.S. patent application having Ser. No. 11/066,788, filed Feb. 25, 2005, and incorporated herein by reference in its entirety.

### FIELD OF THE INVENTION

The present invention relates to electric current sensors. More particularly, the invention relates to a sensor using a dual frequency detection scheme applied to the secondary sensing coil.

### BACKGROUND OF THE INVENTION

There are a number of current sensors used in industrial applications. Example applications include motor control, uninterruptible power supplies, variable speed drives, welding power supplies and the like. There is a trend toward smaller size and lower cost for these current sensors. A number of designs use external magnetic fields, such as, for example, U.S. Pat. No. 3,461,387 which uses three or more coils and it is a device that detects external magnetic fields, not current. The use of a saturated magnetic core has been shown in U.S. Pat. No. 5,239,264 and creates a field current in a coil. U.S. Pat. No. 5,831,432 uses a pair of magneto-impedance elements to cancel out uniform disturbance magnetic fields such as the terrestrial field.

The use of an amorphous wire has been proposed in U.S. Pat. No. 5,994,899. The amplitude of the voltage is asymmetrically varied with a variation in an externally applied magnetic field. A similar use of asymmetrical magneto-impedance is shown in PCT publication WO 02/061445 A1, which is used as a current leakage detector.

U.S. Patent Application Publication No. US 2003/0006765 A1 discloses a sensor coil on an open core, asserting higher accuracy and miniaturization. U.S. Pat. No. 6,512,370 also uses a coil on an open core.

U.S. Pat. No. 5,552,979 determines the measuring current using a high frequency switching circuit which senses the change of flux in the core. However, the circuit is susceptible to transients or drift that can upset the time of the bistable multivibrator and drive the circuit into saturation. The reference proposes circuits to reset the device, but does not prevent it altogether. In once embodiment, there is an offset error from current loading the coil. This is fixed by adding another coil, but at added cost. Further, it relies on saturating the material on every cycle. This can pass transients into the main current to be sensed and place unwanted transients on the sensor output.

U.S. Pat. No. 5,811,965 suggests another method using a transformer signal operating on minor loops and approximating the current to be measured by using the sharpness of the magnetic material's BH curve. However, the approach only crudely approximates the value sensed current since it doesn't sense at the true zero point. Further, the open loop approach is less accurate and more susceptible to variation in material and change over time and temperature than a closed loop approach. The approach is also limited to sensing frequencies two times lower than the AC tickle signal, severely limiting its use in applications requiring fast transient response, (<1 microsecond).

U.S. Pat. No. 4,276,510 drives a high frequency AC source to excite the core while an inductance sensor senses the inductance at points adjacent to peaks of the flux wave and the differences are used to provide a feedback current to another coil to null the current to be sensed. This approach uses three windings: one for the current to be sensed, one for the drive, and one for the feedback. This is a higher cost approach and an approach that reduces the number of coils would be desirable.

In traditional Hall effect and magneto-resistive current sensors, the core is used to concentrate flux on a sensor and to partially shield stray fields. Because these sensors have a gap, it is not possible to completely shield external stray fields. It is also more expensive to manufacture a gap and a discrete sensor component. Hall effect devices also have large offset and offset drift errors.

When the loading of coils is used to sense current, the magnitude of the coil's impedance changes with stray field, temperature, part variation and the like. Thus it is not practical to construct a current sensor that relies on an absolute value of the impedance.

In some devices, it is necessary to have some feedback to improve accuracy. This is not a good solution, however, because an additional coil would be required to provide the feedback signal, thus adding to the cost, size and assembly time.

In a commonly owned, co-pending application having Ser. No. 11/066,788, filed Feb. 25, 2005, the disclosure of which is incorporated herein by reference as if it were fully reproduced herein, detection of electrical current from DC to <1 nsec. is disclosed using a current sensing device that has a rapid response time, high precision response, is small in size, low in cost, and other important properties. That sensor comprises a toroid shaped core having two windings. The first winding contains the primary current of interest. This primary current can be DC or AC. The second winding contains an AC signal that responds such that its instantaneous loading, either as impedance or admittance, corresponds to or is a function of the first or primary current. Typically, only one winding loop is necessary for the primary current of interest. The secondary winding is a plurality of loops, preferably from at least twenty windings. Devices have been made using windings of 30 turns, 100 turns, and 400 turns. The actual number of winding turns is a design variable, depending on the cost and size limitations, magnitude of measured current and the degree of sensitivity and response time needed.

It would be of advantage in the art if a small, inexpensive sensor could be developed that would be limited in response time only by the speed that the toroid material can respond to current impulses.

Yet another advantage would be if a sensor could be provided that is capable of sensing both DC and AC current faster than one nanosecond.

Still another advantage would be if the sensor could discriminate between currents of positive and negative polarities.

It would be another advance in the art if a sensor could be provided with closed loop control by selection of an appropriate frequency in the secondary coil.

Other advantages will appear hereinafter.

### SUMMARY OF THE INVENTION

It has now been discovered that the above and other advantages of the present invention may be obtained in the following manner. Specifically, the present invention provides an electronic frequency detection scheme for a sensing device that has a rapid response time, has a high precision response, is small in size, low in cost, an other important properties.

A sensor device includes a magnetic material having nonlinear magnetic properties within an ambient magnetic flux. The device includes a signal conductor carrying a compound applied electric signal having two frequencies f1 and f2 and coupled to said magnetic material with said ambient magnetic flux to produce a resulting signal. A primary conductor carries a primary current coupled to said magnetic material having nonlinear magnetic properties to change the magnetic flux of said magnetic material and produce said resulting signal.

The magnetic material may be open ended or in the shape of a toroid. In the former case, the device may have a horseshoe shape or other design. In the latter case, the device further includes a primary conductor for carrying a primary current coupled to said magnetic material having nonlinear magnetic properties to change the magnetic flux of said magnetic material and produce said resulting signal. The primary and signal conductors are preferably configured as windings on the toroid. When the applied compound electrical signal having two frequencies is a voltage signal the resulting signal is current and when the signal is a current signal, the resulting signal is a voltage.

The nonlinear properties of the core act as a signal multiplier of the two frequencies resulting in signals at the two frequencies (F and F2) along with their sum and difference (F1+F2 and F1−F2). These last two frequency components are unique in that they not only indicate the magnitude of the current being sensed, but also the polarity or phase of the current.

In one embodiment, f1 may be significantly greater than said f2, and the demodulator includes a first stage at f1 and a second stage at f2. For instance, f1 could be 23 kHz, f2 could be 2.3 kHz. Alternatively, f1 and f2 may be set high and close in value, such that their difference f1−f2 is much lower than f1, f2, and f1+f2. The device would then include a filter to remove f1, f2, and f1+f2, whereby only f1−f2 remains, and thus the demodulator includes just one stage at f1−f2. For example, f1 could be 21 kHz, f2 could be 20 kHz and the resulting f1−f2 would be at 1 kHz.

Because the sense signal is an AC signal, offset and offset drift effects due to the electronics can be virtually eliminated by placing the loop gain before the final demodulation stage. The f1−f2 frequency signal may be then feed back into the secondary winding to oppose the primary current and cancel it. The output of the sensor is the opposing current that is proportional to the measured primary current. It is called a closed loop sensing approach.

### BRIEF DESCRIPTION OF THE DRAWINGS

For a more complete understanding of the invention, reference is hereby made to the drawings, in which:

FIG. 1 is a circuit diagram showing one embodiment of the present invention in which the mechanical components are shown for the basic sensing block of the core and coil;

FIG. 2 is a schematic circuit diagram of an impedance detection circuit used in the present invention;

FIG. 3 is a schematic circuit diagram of an admittance detection circuit used in the present invention;

FIG. 4 is a graph of the output of the circuit of FIG. 2;

FIG. 5 is a graph of the output of the circuit of FIG. 3;

FIG. 6 is a schematic of an example clock circuit used to generate the two frequencies referenced as f1 and f2;

FIG. 7 is a schematic circuit diagram of the dual frequency response circuit of the present invention;

FIG. 8 is a block diagram showing the components of the dual frequency circuit of this invention;

FIGS. 9a, 9b, 9c, 9d and 9e are graphs showing the output at negative polarity for the device shown in FIG. 7;

FIG. 10 is a graph showing the DC open loop response of the present invention;

FIG. 11 is a graph showing the closed loop response of the present invention;

FIG. 12 is a graph showing the AC response of the circuit; and

FIG. 13 is a graph showing the sensor response to a highly non-uniform stray magnetic field.

### DETAILED DESCRIPTION OF THE PREFERRED EMBODIMENT

The present invention provides for substantial improvements in current measuring devices. Specifically, the device of this invention operates based on the way the magnetic properties of a toroid core change with current applied to a wire wrapped around the core. Applied current, called the primary current or current being sensed, generates a magnetic field that becomes trapped in the core. This magnetic field starts to saturate the core. Saturation changes the AC losses and inductance of the core. These changes in core properties is detected as a change in impedance looking into a second coil wrapped around the core.

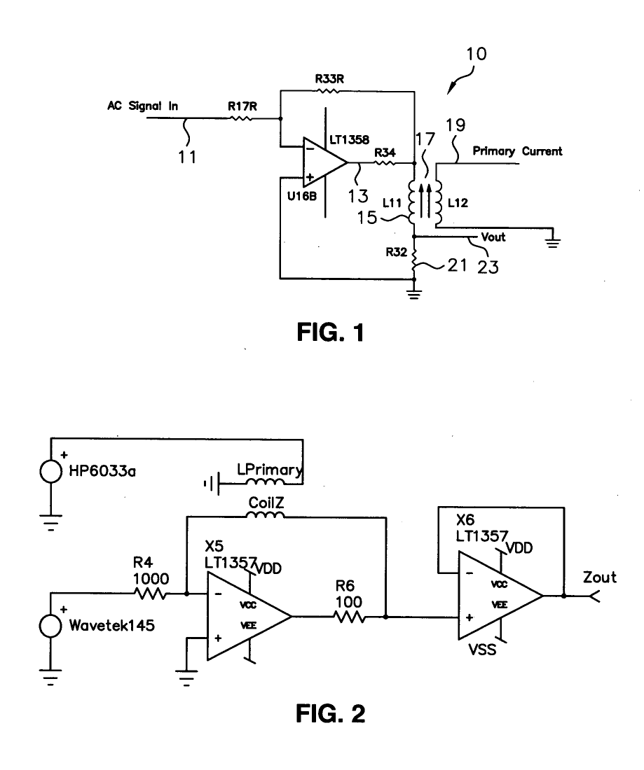

The principal components of the present invention are shown in FIG. 1 as a circuit diagram, 10 generally. An AC signal 11 is introduced through resistor R17, and received by amplifier LT 1358 to place an AC voltage 13 on coil 15. R 34 serves to protect the amplifier, by limiting the current drive of the amplifier U16B. Resistor R34 is placed within the op amp loop so it does not dominate the load at very high admittance changes in the coil.

Coil 15 is a plurality of windings (400 in FIG. 1) around toroid core 17, made in this example from an amorphous magnetic material such as Metglas® 2714. Other materials include permalloys, supermalloys, powder magnetics, ferrites, and other industry standard toroid material with high magnetic permeability and low coercivity. The core has very low coercivity and high permeability. The admittance saturation magnetic filed (i.e., Primary current) is at least 50 times larger than the coercivity of said material, and with Metglas®, this ratio is about 250 or more.

Also passing through toroid core 17 is a primary current 19 which has one winding around said core 17. Current 19 is the current sought to be measured. The sensor of this invention is operable with primary currents from DC current to AC currents up to IM Hz or more. In FIG. 1, the admittance is sensed as the voltage 13 is applied to core 17 and the current 21 is measured in resistor R32 to produce an output signal 23. For a frequency above about 1 to 40 Hz, the secondary coil will act as a transformer mirroring the current in the primary divided by the turns ration (number of turns on the secondary over the number of turns on the primary). The transformer bandwidth is limited at the lower end to about 1 to 40 Hz, depending on sense current magnitude and the resistance in series with the inductor, and at the upper end by the magnetic toroid material. Metglas material responds beyond 35 MHz. The two components give a total frequency response of DC to 35 MHz+. Test results have shown response times of 10 nanoseconds to a 10 amp pulse, but the measurement speed was limited by the test equipment.

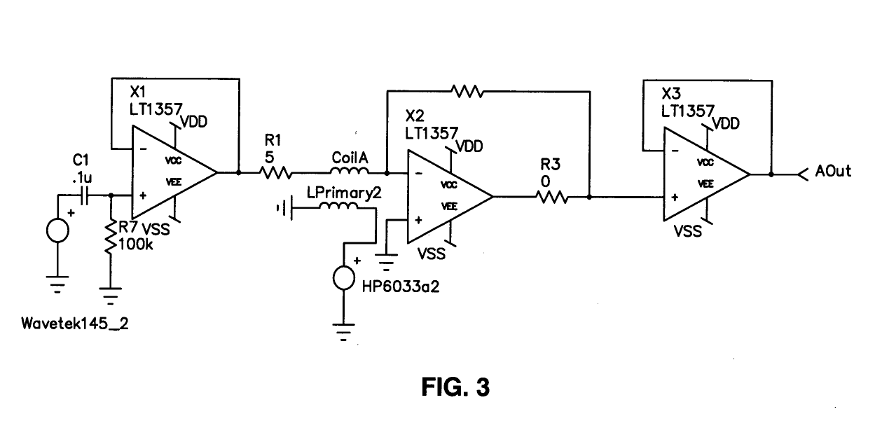

Circuits were built to measure both the impedance and the admittance of the amorphous core. FIG. 2 illustrates an impedance detection circuit and FIG. 3 illustrates an admittance detection circuit. In both cases the core is placed as part of an op-amp block, either as the feedback load for FIG. 2 or the input load in FIG. 3. For a standard inverting op-amp, the transfer function is the ration of the feedback resistor to the input resistor, or Rf/Rin. Substituting the inductor for the RF resistor will give a voltage proportional to the impedance, as in FIG. 2. Substituting the input resist or Rin with the coil will give a voltage proportional to the admittance. Both FIGS. 2 and 3 were used to demonstrate the efficacy of the present invention in both forms. Input and output buffers were used to isolate the coils from the driving amplifiers. In some cases the input signals were AC coupled through capacitors.

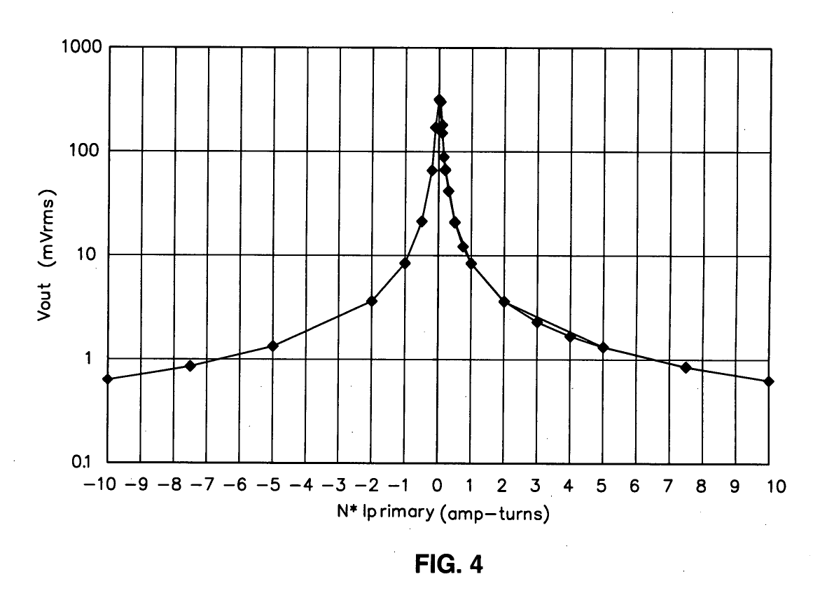

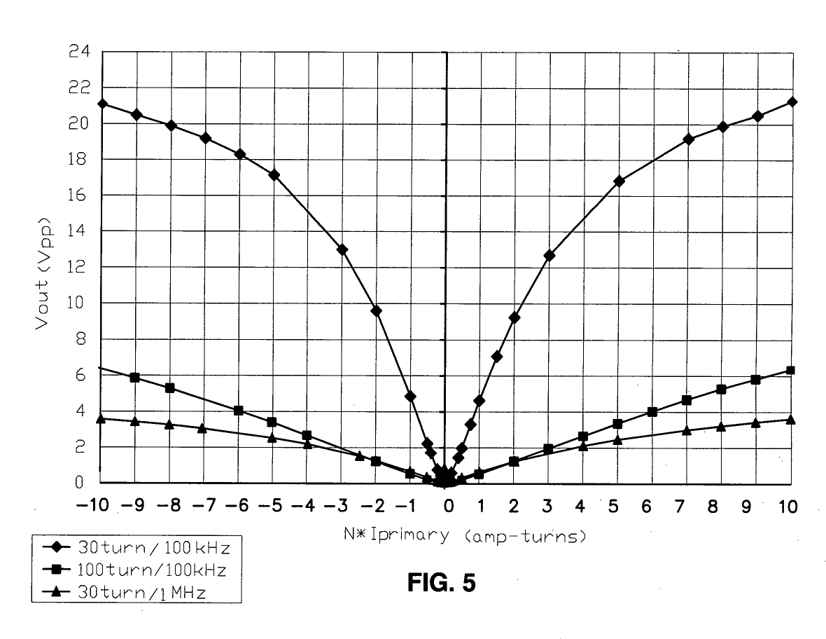

Both circuits shown in FIGS. 2 and 3 were tested with a 100 kHz signal applied by the signal generator and the primary current from the HP6033a adjustable DC power supply was adjusted over the ±10 amp range. For the impedance tests using the circuit of FIG. 2, the coil had 30 turns. The output signals are shown in FIG. 4. In the admittance test, the coil was tested with both 30 turns and 100 turns, with the results shown in FIG. 5.

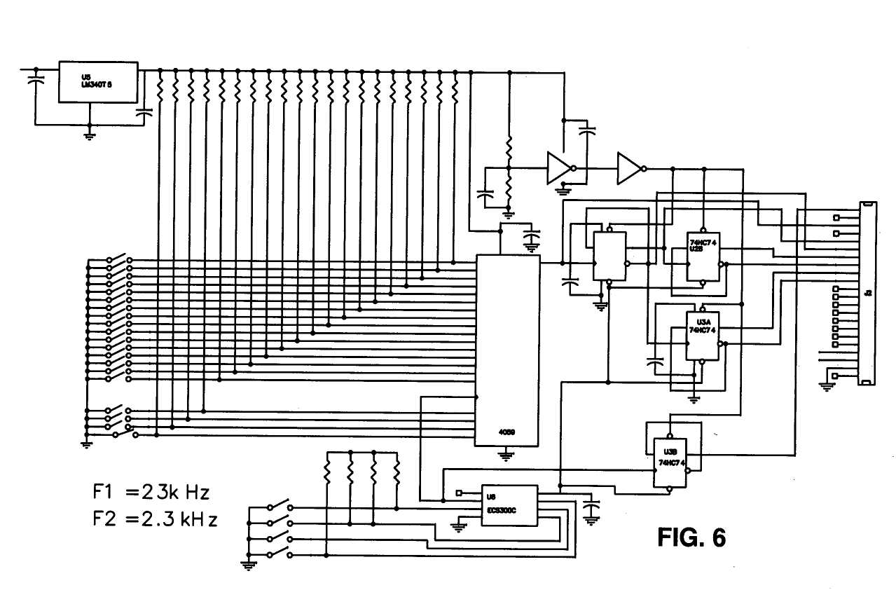

FIG. 6 is an example clock circuit to generate the signals F1 and F2. Other forms are also useful, including the use of a microprocessor or a programmable logic device.

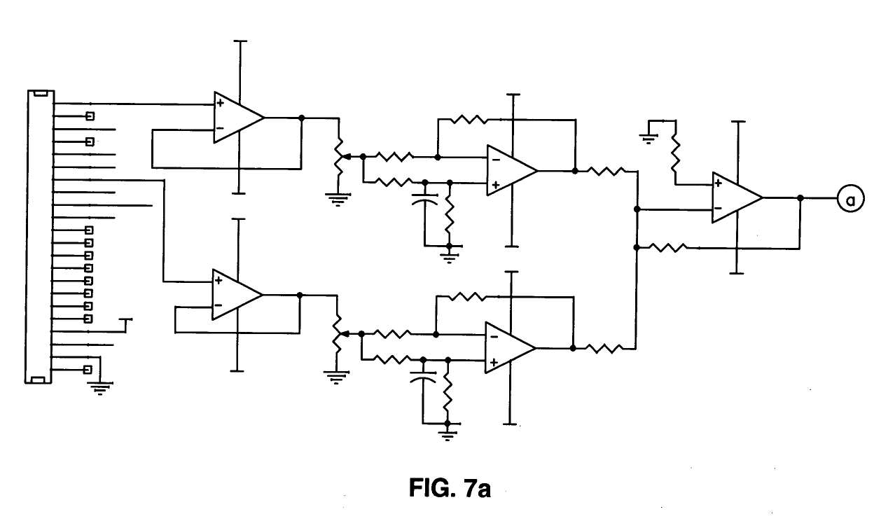

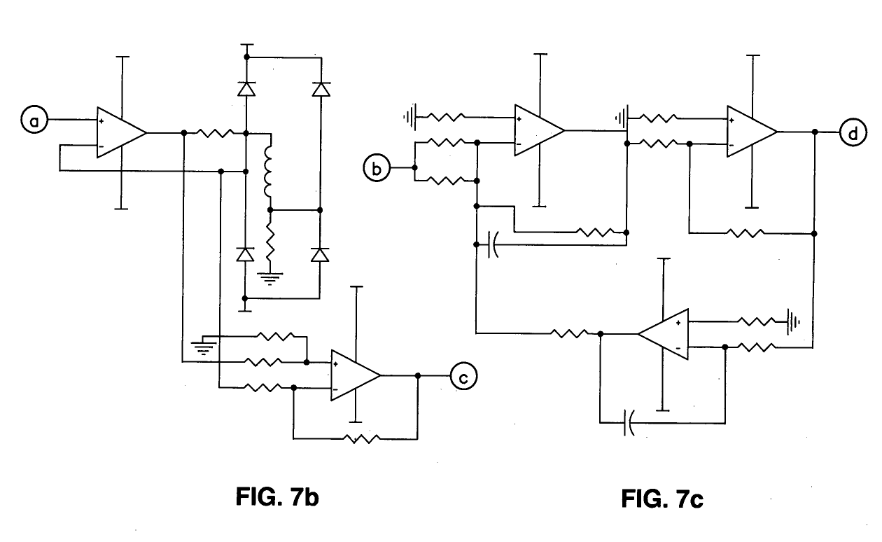

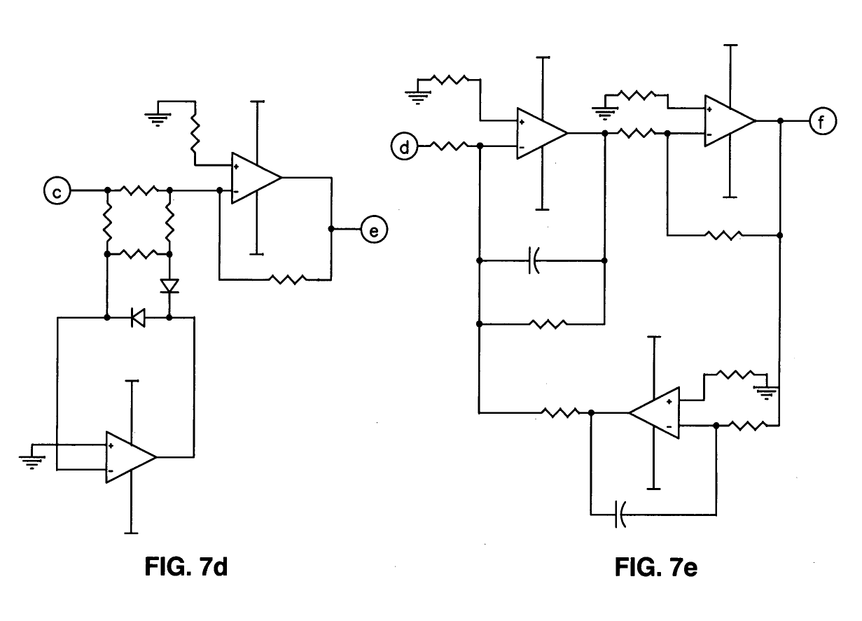

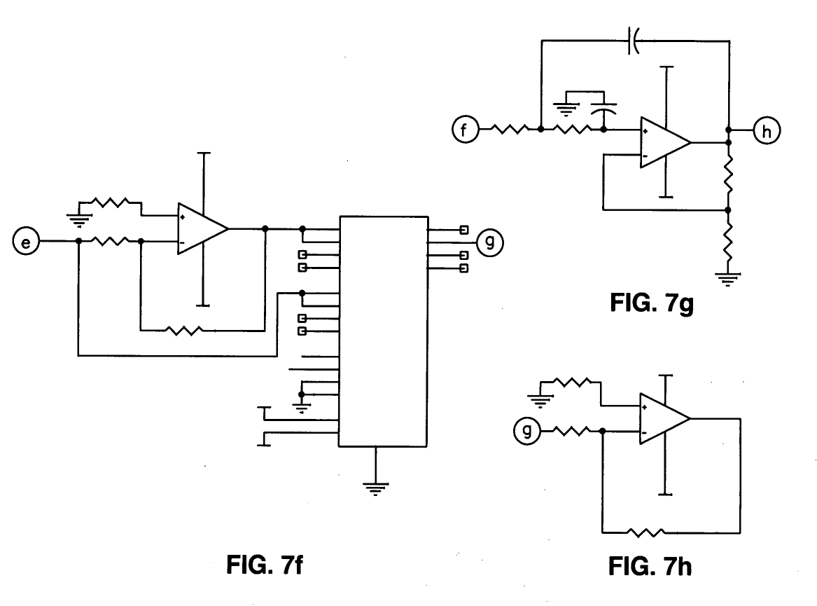

FIG. 7 is a schematic of the dual frequency circuit used in the present invention to produce a signal related in magnitude and polarity and phase to the primary current signal being measured. The schematic, 20 generally, includes a connector 21 to a clock circuit that provides a high frequency signal F 1 and a low frequency signal F2. The signals F 1 is a multiple of F2, referenced to the digital system clock. In a preferred embodiment, F1=N*F2 where N is an integer ranging from 5 to 15, although other integers are within the scope of this invention. Most preferred is N=10. In one example, F1 is 23 kHz and F2 is 2.3 kHz. The output of connector 21 is F1 and Qi, where Qi is the in phase part of low frequency F2.

F1 and F2 are coupled in coupler 23, which takes the output of connector 21, buffers the signals and AC couples them, sending the coupled signal to summer 25, which adds the two frequency components into a summed signal. With a closed loop signal, discussed below, a feedback signal can be applied to summer 25 as well.

The summed signal is fed to op amp 27, which acts as a buffer and has a load limiting-resistor to prevent from railing the current limit of the amplifier (30 mA for example). Op amp 27 drives the core of the toroid, and an optional load resistor, to ground. Diodes may be included in op amp 27 to prevent voltages from going beyond the rails.

Amplifier stage 29 is a differential amplifier that measures the voltage across the protection resistor in op amp 27 to give the current in the toroid core and can be used for later electronic processing. The output from amplifier stage 29 is received by a 2 pole bi-quad bandpass filter 31 that passes the high frequency component (F1) in the signal that has sidebands differing in frequency by F2 (F1±F2). The output of bandpass filter 3 is received by a full wave rectifier 33 that demodulates the high frequency down to DC. The output of rectifier 33 are components at F2 (2.3 kHz sidebands), when the exemplary frequencies set out above are used, and at 2*F1. This output goes to a 2 pole bi-quad bandpass 35 which passes only the 2.3 kHz signal which has a magnitude and phase proportional to the primary current and filters out the 2*F1 signal. This signal is fed into a single pole dual throw analog switch 37 for demodulation at the low frequency (F2), also known as synchronous rectification. One pin in switch 37 outputs the in phase component and another pin outputs the quadrature component. Finally, a 2 pole low pass filter 39 (for example at 160 Hz and 16 Hz) filters the demodulated signal. This filtered signal is what is used for closed loop control or as the open loop output.

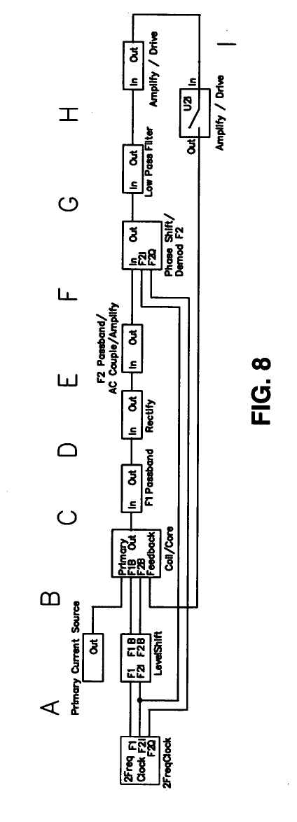

FIG. 8 is a block diagram of the dual frequency circuit used in the present invention to produce a signal related in magnitude, phase and polarity to the primary signal being measured. The 2 frequency clock generates the signals F1 and F2 along with the demodulation reference. An example circuit is shown in FIG. 6. The level shift block is coupler 23 in FIG. 7. The coil core block is made up of items 25, 27 and 29 of FIG. 7 as described above. FIG. 7 also shows the F1 bandpass block 31, The rectify block 33, the F2 passband/AC Couple/amplify block 35, the phase shift/demod F2 block 37, and low pass filter block 39. The switch U21 in FIG. 8 closes the loop. Elements in FIG. 8 are also identified in FIG. 7.

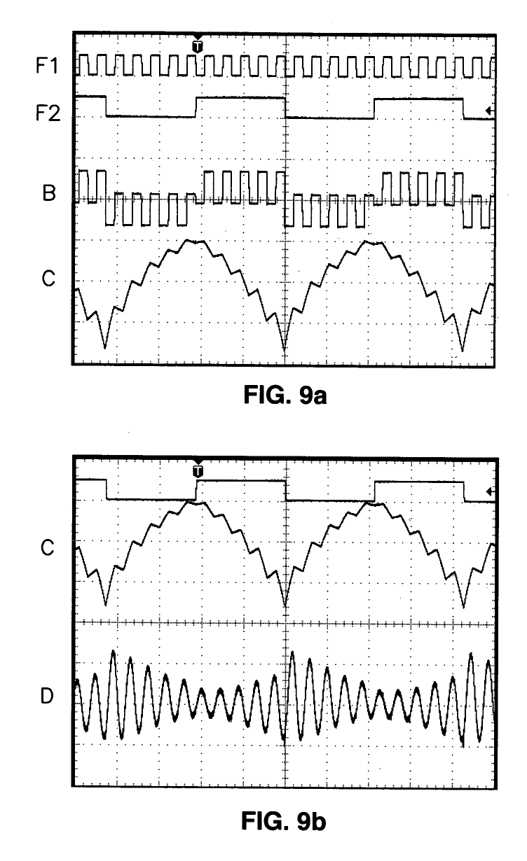

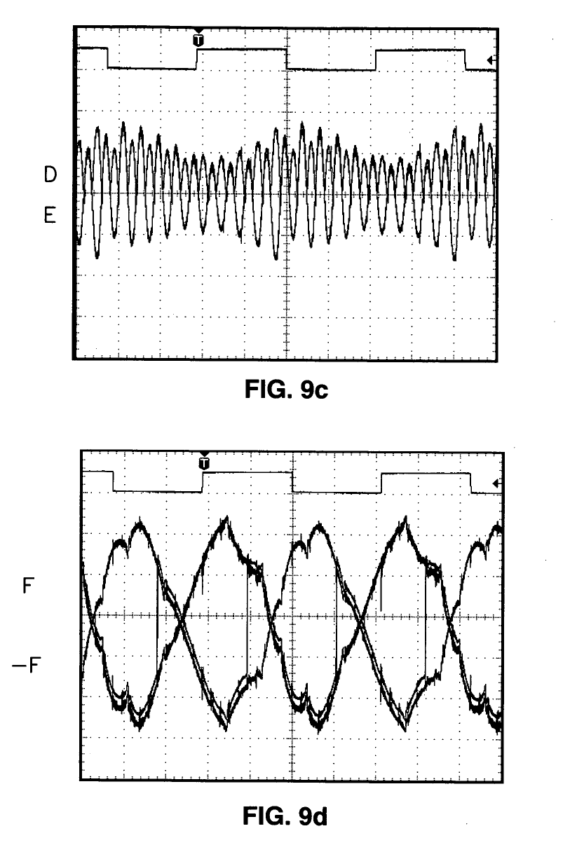

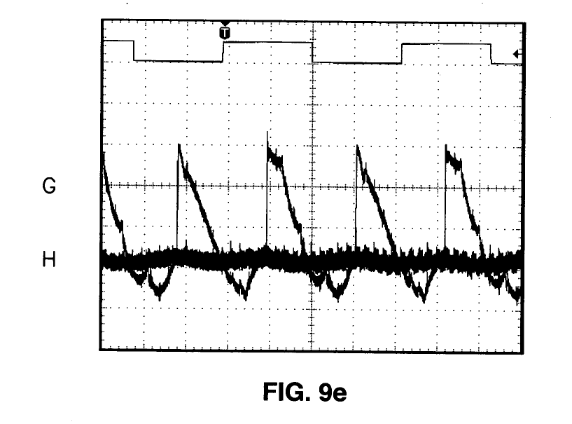

FIG. 9 shows signals out of the circuit at different points referenced in FIGS. 7 and 8. In FIG. 9a, trace 1 is the F 1 signal and trace 2 is the F2 signal from the clock circuit A in FIGS. 7 and 8). Trace 3 is the AC coupled sum of the two signals (B). Trace 4 is the current in coil (C). FIG. 9b shows this signal (trace 2) and the signal after the bandpass filter (trace 3) D. The primary signal is at F1, but it is amplitude modulated by F2. FIG. 9c shows the effect of the rectifier (E). FIG. 9d shows the output after the second bandpass filter (F). Note that up until this point, the sensed signal has been completely AC. Therefore no DC errors from sensing nor electronics has entered into the system yet. Therefore gain is typically added in the filters such that the closed loop response has virtually no offset nor offset drift due to electronics. FIG. 9c shows the signal after demodulation (G) and then after that signal is filtered (H). The final signal (H) is the open loop response or the signal that can be fed back in closed loop operation.

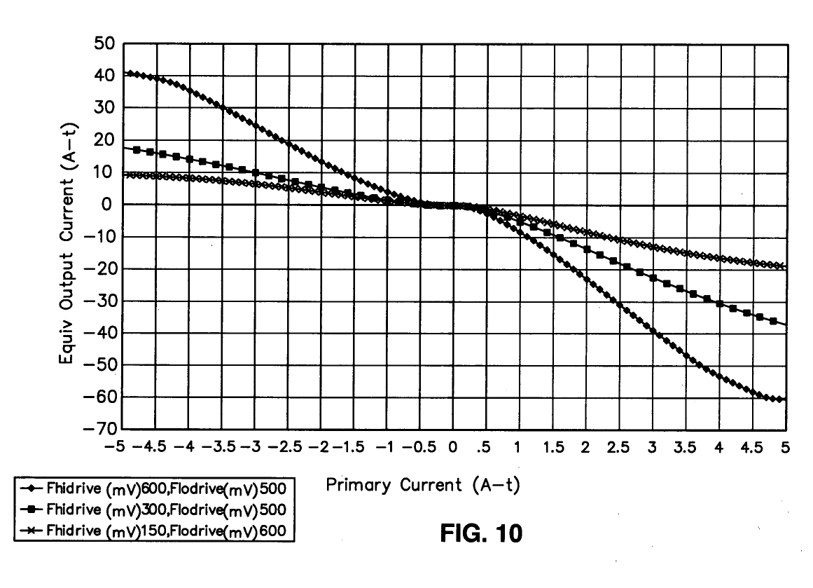

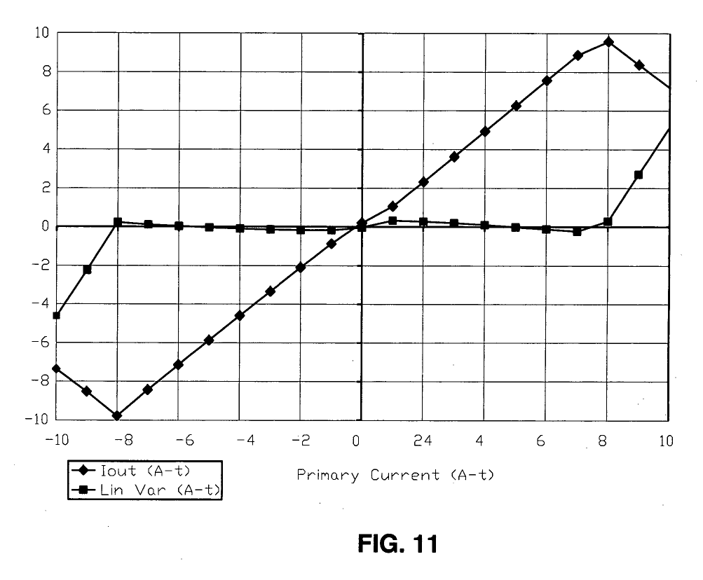

FIG. 10 shows the open loop response of the sensor of this invention. FIG. 11 shows the closed loop response. Changing circuit parameters allows the range to be extend beyond the ±8 amps shown here.

FIG. 12 shows the AC response of the sensor to a 10 amp-turn pulse on the primary conductor. Note that the secondary current, which is the sensor output, mirrors the rise of the primary current within about a nanosecond. FIGS. 11 and 12 show how the sensor responds from DC to about a nanosecond.

FIG. 13 shows the sensor's insensitivity to stray magnetic field. In this case a copper conductor with −2 to +26 amps was placed next to the sensor so they are in contact. The conductor was placed for maximum disturbance. The error signal was recorded and is plotted here in FIG. 13. For 25 amps directly next to a 10 amp sensor, the maximum error was 0.0013% of full scale (10 amps). That is only 13 parts per million variation in output when a current two and a half times larger than the full scale value is placed next to the sensor. Traditional gapped core and no core current sensors have sensitivities to stray magnetic-field from a conductor from 500 to 5000 times larger than this.

In addition to feeding the analog output of the circuit back to the summing amplifier, alternately, this signal could control a fixed frequency pulse width modulation circuit at F1. This would generate the F1 signal. A small change in the duty cycle can be used to provide a feedback signal while retaining the maximum swing of the AC drive signals (0 to 5 V, for example).

It should be noted that the devices of the present invention can readily have many configurations. Of particular interest are configurations that are integrated with Mechanical Electrical Microsystem integrated circuits or circuit board technologies, and such are within the scope of this invention.

While particular embodiments of the present invention have been illustrated and described, it is not intended to limit the invention, except as defined by the following claims.

1. A sensor device comprising:
a magnetic material having nonlinear magnetic properties within an ambient magnetic flux;
a signal conductor carrying a compound applied electric signal having two frequencies f1 and f2 and coupled to said magnetic material with said ambient magnetic flux to produce a resulting signal; and
electrical means for detecting said resulting signal at the frequencies f1+f2 or f1−f2 using a demodulation of the signal to thereby create a low frequency signal centered at DC f3 related to said ambient magnetic flux's magnitude and phase which, for DC magnetic flux becomes the polarity.

2. The device of claim 1, wherein said magnetic material and signal conductor are integrated with a MEMS integrated circuit or circuit board.

3. The device of claim 1, wherein said magnetic material has two ends and an open shape with a gap between said two ends.

4. The device of claim 3, wherein said magnetic material and said signal conductor are integrated with a MEMS integrated circuit or circuit board.

5. The device of claim 1, which further includes a primary conductor for carrying a primary current coupled to said magnetic material having nonlinear magnetic properties to change the magnetic flux of said magnetic material and produce said resulting signal; and
said electrical means for detecting said resulting signal and creates a low frequency signal f3 related to the primary current's magnitude and phase.

6. The device of claim 5, wherein said magnetic material and said primary and signal conductors are integrated with a MEMS integrated circuit or circuit board.

7. The device of claim 5, wherein said magnetic material is in the shape of a toroid.

8. The device of claim 7, wherein said primary and signal conductors are configured as windings on said toroid.

9. The device of claim 5, which includes a feedback loop for carrying signal f3 back to said secondary conductor to cancel the magnetic field created by said primary current to thereby form a closed loop device.

10. The device of claim 9, wherein said loop is closed by connecting the signal from the open loop circuit and summing it with a compound applied signal having two frequency f1 and f2.

11. The device of claim 9, wherein said loop is closed by connecting the signal from the open loop circuit to a fixed frequency pulse width modulation circuit where said pulse width modulation circuit generates signal f1 or f2 and it has a duty cycle proportional to the feedback error signal.

12. The device of claim 9, wherein said closed loop frequency response operates above the low end of a transformer effect frequency to thus provide a response from DC to the fastest response of the magnetic material operating as an open loop transformer.

13. The device of claim 9, wherein the system gain is placed before the final demodulation stage to eliminate offset and offset drift errors.

14. The device of claim 1 wherein said applied compound electrical signal having two frequencies is a voltage signal whereby said resulting signal is current.

15. The device of claim 1 wherein said applied compound electrical signal having two frequencies is a current whereby said resulting signal is voltage.

16. The device of claim 5, wherein said f1 is significantly greater than said f2, and said 2 demodulator includes a first stage at f1 and a second stage at f2.

17. The device of claim 5, wherein f1 and f2 are high and close in value, such that their difference f1−f2 is much lower than f1, f2, and f1+f2, and wherein said device includes a filter to remove f1, f2, and f1+f2, whereby only f1−f2 remains, and said demodulator includes 1 stage at f1−f2.

18. A sensor device comprising:
magnetic material means for having nonlinear magnetic properties within an ambient magnetic flux;
signal conductor means for carrying a compound applied electric signal having two frequencies f1 and f2 and coupled to said magnetic material with said ambient magnetic flux to produce a resulting signal; and
electrical means for detecting said resulting signals at the frequencies f1+f2 or f1−f2 using demodulation means of the signals for creating a low frequency signal f3 related to said ambient magnetic flux's magnitude and phase

19. The device of claim 18, wherein said magnetic material means and signal conductor means are integrated with a MEMS integrated circuit or circuit board means.

20. The device of claim 18, wherein said magnetic material has two ends and an open shape with a gap between said two ends.

21. The device of claim 20, wherein said magnetic material means and signal conductor means are integrated with a MEMS integrated circuit or circuit board means.

22. The device of claim 18, which further includes primary conductor means for carrying a primary current coupled to said magnetic material means having nonlinear magnetic properties to change the magnetic flux of said magnetic material means and produce said resulting signal; and
said electrical means for detecting said resulting signal and creates a low frequency signal f3 related to the primary current's magnitude and phase.

23. The device of claim 22, wherein said magnetic material means, said primary conductor means and said signal conductor means are integrated with a MEMS integrated circuit or circuit board means.

24. The device of claim 18, wherein said magnetic material means is in the shape of a toroid.

25. The device of claim 24, wherein said primary and signal conductor means are configured as windings on said toroid.

26. The device of claim 22, which includes a feedback loop means for carrying signal back to said secondary conductor means to cancel the magnetic field created by said primary current to thereby form a closed loop device.

27. The device of claim 26, wherein said loop is closed by connecting the signal from the open loop circuit and summing it with a compound applied signal having two frequency f1 and f2.

28. The device of claim 26, wherein said loop is closed by connecting the signal from the open loop circuit to a fixed frequency pulse width modulation circuit where said pulse width modulation circuit generates signal f1 or f2 and it has a duty cycle proportional to the feedback error signal.

29. The device of claim 26, wherein said closed loop frequency response operates above the low end of a transformer effect frequency to thus provide a response from DC to the fastest response of the magnetic material operating as an open loop transformer.

30. The device of claim 26, wherein the system gain is placed before the final demodulation stage to eliminate offset and offset drift errors.

31. The device of claim 18, wherein said applied compound electrical signal having two frequencies is a voltage signal whereby said resulting signal is current.

32. The device of claim 18, wherein said applied compound electrical signal having two frequencies is a current whereby said resulting signal is voltage.

33. The device of claim 22, wherein said f1 is significantly greater than said f2, and said demodulator includes a first stage at f1 and a second stage at f2.

34. The device of claim 22, wherein f1 and f2 are high and close in value, such that their difference f1−f2 is much lower than f1, f2, and f1+f2, and wherein said device includes a filter means for removing f1, f2, and f1+f2, whereby only f1−f2 remains, and said demodulator means includes 1 stage at f1−f2.
